(19) United States
(12) Patent Application Publication
(10) Pub. No.: US 2010/0193234 A1
(43) Pub. Date: Aug. 5, 2010

(54) Method for producing an electrical and mechanical connection and an assembly comprising such a connection

(75) Inventors: Sebastian Kisban, Munchen (DE); Ulrich Bartsch, Freiburg (DE); Patrick Ruther, Karlsruhe (DE); Johannes Kenntner, Karlsruhe (DE); Oliver Paul, Au (DE)

Correspondence Address: THE WEBB LAW FIRM, P.C., 700 KOPPERS BUILDING, 436 SEVENTH AVENUE, PITTSBURGH, PA, 15219, US

(73) Assignee: ALBERT-LUDWIGS-UNIVERSITAT FREIBURG, Freiburg (DE)

(21) Appl. No.: 12/689,780

(22) Filed: Jan. 19, 2010

(30) Foreign Application Priority Data
Jan. 23, 2009 (DE) 10 2009 005 996.2

(51) Int. Cl. H05K 1/00; H01R 43/16; H01R 43/26

(52) U.S. Cl. 174/268; 29/877

(57) ABSTRACT

A method for producing an electrical and mechanical connection, wherein a solid body comprises a support, on which is disposed an electrical contact zone and an electrically insulating support zone. A flexible, flat cable comprises a support layer made of an electrically insulating material and a strip conductor, with an electrical contacting point and a laterally adjacent insulating cable zone. An adhesive layer is applied on the cable and the contacting point is disposed on the support layer so that the adhesive layer surrounds the contacting point and adheres to the cable. The support and the cable are positioned in a pre-assembly position so that the contacting point of the cable is facing the contact zone of the support and the adhesive layer is facing the electrically insulating support zone. The solid body and the cable are positioned so that the contacting point electrically contacts the contact zone and the adhesive layer adheres to the surface of the solid body.

The invention relates to a method for producing an electrical and mechanical connection, wherein provision is made of a solid body that has a support on the surface of which is disposed at least one electrical contact zone and an electrically insulating support zone surrounding the latter, wherein provision is made of a flexible, flat cable that has at least one flat support layer made of an electrically insulating material and at least one strip conductor disposed thereon, which has at least one electrical contacting point with a laterally adjacent electrically insulating cable zone on the surface of the cable, and wherein the cable and the solid body are positioned relative to each other in a preassembly position and the contact zone is electrically connected to the contacting point. The invention further relates to an assembly comprising a flexible flat cable and a solid body connected thereto, wherein the solid body has a support on the surface of which are disposed at least one electrical contact zone and an electrically insulating support zone surrounding the latter, wherein the cable has at least one flat support surface made of an electrically insulating material and at least one strip conductor disposed thereon, which has at least one electrical contacting point with a laterally adjacent electrically insulating cable zone on the surface of the cable, and wherein the contacting point is electrically connected to the contact zone.

Such a method and such an assembly are disclosed in Meyer, Jörg-Uwe et al. “High Density Interconnects and Flexible Hybrid Assemblies for Active Biomaterial Implants”, IEEE Transactions on Advanced Packaging, vol. 24, no. 3 (Aug. 3, 2001). In the method, provision is first made of a flexible cable. In a first procedural step, a polyimide layer is applied to an auxiliary substrate by rotational casting. A strip conductor structure is formed on the polyimide layer, wherein an electroplating is sputtered and lithographically structured. The electroplating and the laterally adjacent surface zones of the polyimide layer are planarly coated with an electrical insulation layer in a further procedural step. On this layer is applied a second electroplating from which is formed a contacting structure, which is electrically connected by means of through connections to the strip conductor structure. Breakthroughs are formed in the contacting structures in the layer sequence thus obtained. An additional insulating polyimide layer is applied on the layer sequence and the cable thus obtained is then removed from the auxiliary substrate.

Further provision is made of a solid body, which has as a support a semiconductor chip, on the surface of which are disposed electrical contact zones that are surrounded by electrically insulating support zones.

In another procedural step, the cable and the support are positioned in a preassembly position relative to each other in such a way that the cable breakthroughs are aligned over the contact zones of the solid body and the contacting structure of the cable is facing away from the contact zones. A bonding capillary is then positioned on the individual contact zones one after the other, in order to attach a bonding ball to each of the contact zones by applying pressure, temperature, and ultrasound energy. The bonding ball fuses with the contact zone and the contacting structure, thereby establishing an electrical connection between the respective contact zone and the contacting structure.

A disadvantage resides in the method in that it is only possible to attach the individual bonding balls one after another to the contact zones. Carrying out the method is hence relatively time consuming. Another disadvantage resides in the fact that the electrical connection between the contact zones and the contacting structure has but limited mechanical stability. In applications in which the cable may be subjected to mechanical stresses, such as in medical implants, the connection point therefore needs to be reinforced. A further disadvantage of the method resides in the fact that the electrical connections between the contact zones and the contacting structure are but poorly protected against corrosion. In applications in which the assembly may come into contact with moisture or aggressive media, an encapsulation, such as a silicon coating, must therefore be applied to the contact zones in order to improve the long-term stability of the electrical connection and to prevent surface leakage. Furthermore, the fact that the bonding balls protrude above the surface of the ribbon cable is also disadvantageous. Hence the overall height of the electrical connection between the contact zones and the contacting structure is relatively large.

Hence the object is to create a method of the aforementioned type that enables the simple and easy production of an electrical connection between the solid body and the cable that is protected from vapor and liquid media penetration. A further object is the provision of an assembly of the aforementioned type which is easy and economical to manufacture and in which the contact zone and the contacting point are protected from contact with moisture or other liquid media.

This object is achieved for the method wherein an electrically insulating adhesive layer is applied in such a way to the cable surface and disposed in such a way on the support layer that the adhesive layer uninterruptedly surrounds the contacting point and adheres to the cable surface, wherein the solid body and the cable in the preassembly position are then positioned in relation to each other in such a way that the contacting point of the cable is facing the contact zone of the solid body and the adhesive layer is facing the electrically insulating support zone, and wherein the solid body and the cable are then positioned against each other in such a way that the contacting point electrically contacts the contact zone and the adhesive layer adheres to the surface of the solid body.

With the method of the invention, it is possible to achieve, in a single step, an electrical connection between the contacting point of the cable and the contact zone of the solid body while simultaneously achieving a stable, planar mechanical connection between the cable and the solid body. Because the adhesive layer uninterruptedly surrounds the contacting point and the contact zone and is connected to both the surface of the cable and the surface of the solid body in such a way as to form a seal, the adhesive layer can also serve as a means of encapsulation, thus protecting the contacting point and the contact zone from vapor or liquid media penetration. In an advantageous manner, with the method it is even possible to achieve the electrical and mechanical connection and encapsulation simultaneously for a plurality of contacting points laterally spaced apart from each other provided on the cable and a contact zone of the solid body assigned to each of said contacting points. With the application of the adhesive layer to the cable, preference is given to the simultaneous application of the adhesive layer to a plurality of cables pre-formed on an auxiliary substrate. Hence the method can be carried out even faster and more economically in the scope of mass production. The adhesive layer can be bonded to a surface zone of the solid body surrounding the contact area by applying pressure, heat, and/or ultrasound energy. The adhesive layer can either consist of or contain an adhesive.

In an advantageous embodiment of the invention, provision is made of the solid body in such a way that relative to a laterally adjacent surface zone of the solid body, the contact zone protrudes perpendicular to the extension plane of the support, wherein the adhesive layer and the contacting point are disposed on the surface of the cable and on the surface of the support, respectively, in such a way that the adhesive layer has an opening at the contacting point and with its rim zone surrounding the opening perpendicular to the plane in which the cable extends, protrudes relative to the contacting point, and wherein the solid body and the cable are positioned against each other in such a way that the contact zone contacts the contacting point through said opening. Hence an even more stable mechanical connection between the cable and the solid body is achievable. The contact zone can be formed by an electroplating, which is applied either directly or indirectly over at least one intermediate layer on the support. Initially the adhesive layer can be applied to the whole surface of the cable, and then removed area-wise from the surface of the cable at the points at which the openings should be.

Preference is given to the cross-section of a section of the opening for accommodating the contact structure in the assembly position being somewhat larger than the cross-section of the protruding part of the contact structure, wherein during and/or after the positioning of the solid body and the cable against each other, at least the rim zone of the adhesive layer adjacent to the opening is heated above the vitrification temperature of the adhesive layer, wherein pressure is applied to the rim zone in such a way that the latter is displaced towards the contact structure and comes into contact therewith, and wherein the temperature of the rim zone is cooled below the vitrification temperature afterwards. The contact zone is then more easily inserted in the opening during assembly, as initially there is a lateral gap between the contact structure and the rim zone surrounding the recess. This gap is then filled with the rim zone material by the rim zone being heated and then displaced towards the contact structure, until the latter joins together with the rim zone in a formfitting manner. A sealed and formfitting connection between the contact structure and the adhesive layer is thus achievable.

In another advantageous embodiment of the invention, the adhesive layer and a contacting structure are applied to the support layer in such a way that relative to a laterally adjacent surface zone of the adhesive layer, the contacting structure protrudes perpendicular to the extension plane of the support and forms the contacting point on its free end zone facing away from the support layer, wherein the contact zone is disposed in a recess of the support zone, and wherein the solid body and the cable are positioned against each other in such way that the contacting point contacts the contact zone through the recess. A stable mechanical connection between the cable and the solid body is likewise achievable in this manner.

In a preferred embodiment of the invention, a cross-section of a section of the recess for accommodating the contacting structure in the assembly position is somewhat larger than the cross-section of the part of the contacting structure that protrudes relative to the surface zone of the adhesive layer, wherein during and/or after the positioning of the solid body and the cable against each other, at least the rim zone of the electrically insulating support zone adjacent to the recess is heated above the vitrification temperature of the rim zone, wherein pressure is applied to the rim zone in such a way that the latter comes into contact with the contacting structure and/or with the support zone in the recess, and wherein the temperature of the rim zone is cooled below the vitrification temperature afterwards. During assembly the contacting structure is then more easily inserted in the recess, as initially there is a lateral gap between the contacting structure and the rim zone surrounding the recess. This gap is then filled with the rim zone material by heating the rim zone to the vitrification temperature and then displacing it towards the contacting structure, until the latter joins together with the rim zone in a formfitting manner. A sealed and formfitting connection between the contact structure and the adhesive layer is thus achievable.

The aforementioned object can also be achieved for the method by applying an adhesive layer to the surface of the solid body and disposing the contact zone on the support in such a way that the adhesive layer uninterruptedly surrounds the contact zone and adheres to the surface of the solid body, wherein the solid body and the cable are positioned in relation to each other in the preassembly position in such a way that afterwards the contacting point of the cable is facing the contact zone of the support and the adhesive layer is facing the electrically insulating cable zone, and then by positioning the support and the cable against each other in such a way that the contacting point electrically contacts the contact zone and the adhesive layer adheres to the surface of the cable.

With this solution it is likewise possible to establish an electrical and mechanical connection easily between the contacting point of the cable and the contact zone of the solid body, wherein the adhesive layer can also serve as an encapsulation means. The method also enables the achievement of a simultaneous electrical and mechanical connection of a plurality of laterally spaced apart contacting points provided on the cable to a contact zone of the solid body assigned to each of said contacting points. The application of the adhesive layer on the solid body is preferably achieved simultaneously for a plurality of integrally interconnected solid bodies. The solid bodies are separated afterwards. The adhesive layer can be joined together with a surface zone of the cable surrounding the contacting point by applying pressure, thermal energy, and/or ultrasound energy. The adhesive layer can consist of or contain an adhesive. If necessary, in addition to the first adhesive layer provided on the surface of the solid body, a second adhesive layer can be disposed on the cable surface, which is in the preassembly position of the first adhesive layer.

It is advantageous if the adhesive layer is applied to the surface of the solid body and the contact zone is disposed on the support in such a way that the contact structure protrudes relative to a laterally adjacent surface zone of the adhesive layer perpendicular to the extension plane of the surface zone and forms the contact zone on its free end zone facing away from the support, wherein the contacting point is disposed in an opening of the electrically insulating cable zone, and wherein the solid body and the cable are then positioned against each other in such a way that the contact zone contacts the contacting point through the recess. Hence the method enables the achievement of a good mechanical connection between the cable and the solid body.

Advantageously, the cross-section of a section of the opening for accommodating the contact structure in an assembly position is chosen so that it is somewhat larger than the cross-section of the part of the contact structure that protrudes relative to the surface zone of the adhesive layer, wherein during and/or after the positioning of the solid body and the cable against each other, at least the rim zone of the electrically insulating cable zone adjacent to the opening is heated above the vitrification temperature of the rim zone, wherein pressure is applied to the rim zone in such a way that the latter comes into contact with the contact structure and/or the electrically insulating cable zone in the recess, and wherein the temperature of the rim zone is cooled below the vitrification temperature afterwards. This method likewise enables an easy insertion of the contact zone in the opening during assembly. During assembly the rim zone material is laterally displaced towards the contact structure until the latter joins together with the contact structure in a formfitting manner.

In another advantageous embodiment of the invention, the adhesive layer and the contact zone are applied to the support in such a way that the adhesive zone has a recess at the contact zone and with its rim zone surrounding the recess perpendicular to the extension plane of the support, protrudes relative to the contact zone, wherein a contacting structure is applied to the support layer in such a way that the contacting structure, relative to a laterally adjacent surface zone, protrudes perpendicular to the extension plane of said surface zone and forms the contacting point on its free end zone facing away from the support layer, and wherein the solid body and the cable are then positioned against each other in such a way that the contacting point contacts the contact zone through the recess.

In order to simplify assembly, also in the aforementioned embodiment of the invention the cross-section of a section of the recess for accommodating the contacting structure in the assembly position can be chosen so that it is somewhat larger than the cross-section of the part of the contacting structure that protrudes relative to the surface zone of the electrically insulating cable zone, wherein during and/or after the positioning of the solid body and the cable against each other, at least the rim zone of the adhesive layer adjacent to the recess is heated above the vitrification temperature of the rim zone, wherein pressure is applied to the rim zone in such a way that the latter comes into contact with the contacting structure, and wherein the temperature of the rim zone is cooled below the vitrification temperature afterwards.

If necessary, a polymer layer can be applied as an insulation layer to the support layer and the electroplating. The at least one strip conductor can then be disposed between the support layer and the polymer layer, so that it is at least section-wise encapsulated by these layers. Provision can be made of an opening in the polymer layer at the contacting point. Preference is given to the polymer layer being composed of polyimide and/or Parylene. In particular, the polymer layer can be composed of the same material as the support layer.

In a preferred embodiment of the invention, during and/or after the positioning of the solid body and the cable against each other, the contacting point is welded by ultrasound to the contact zone. Doing so ensures a long-term stable electrical connection in spite of the high flexibility and resilience of the cable. Welding by ultrasound prevents heat damage to the temperature-sensitive flexible cable, which could otherwise occur with soldering, for example.

The aforementioned object for the assembly of the abovementioned type is achieved by the contacting point facing the contact zone, and by an adhesive layer being disposed between and uninterruptedly surrounding the cable and the solid body, wherein the adhesive layer planarly adheres to the surface of the solid body and to the surface of the cable.

The adhesive layer thus forms an encapsulation for the contacting point and the contact zone and also serves as a mechanical connection for fastening the cable to the solid body. Preference is given to the adhesive layer being composed of a fluoride polymer, which is sold by the Asahi Glass Company under the trade name Cytop®.

Illustrative embodiments of the invention are explained in more detail in the following, with reference to the drawing. Shown are:

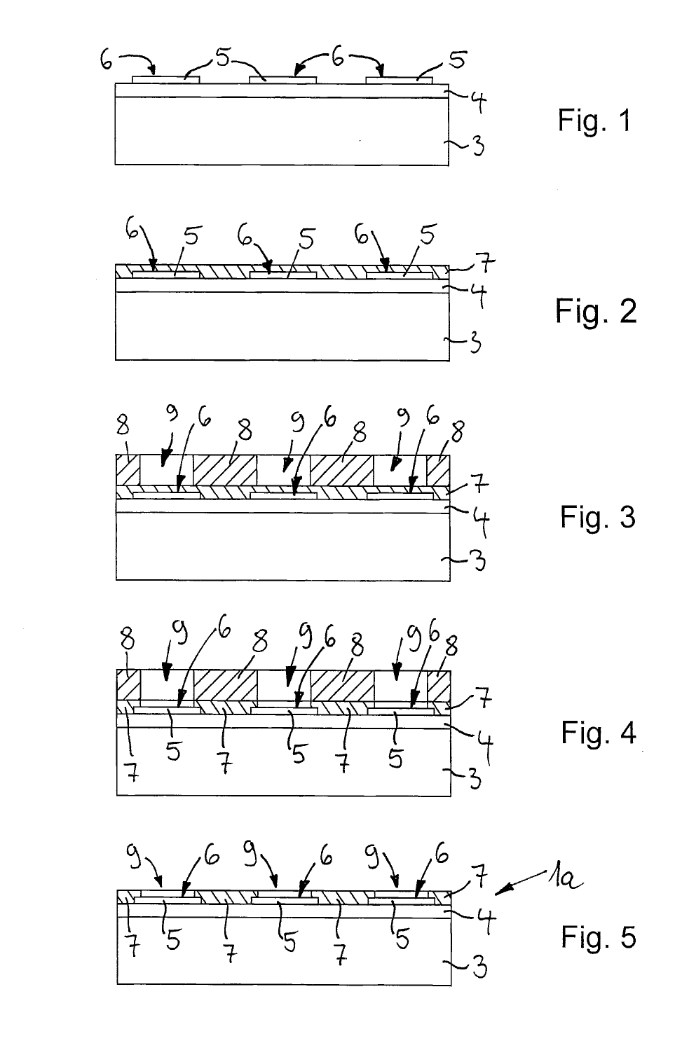

FIGS. 1

through 5 a cross-section through an auxiliary substrate, on which were applied layers for the manufacture of a first flexible ribbon cable,

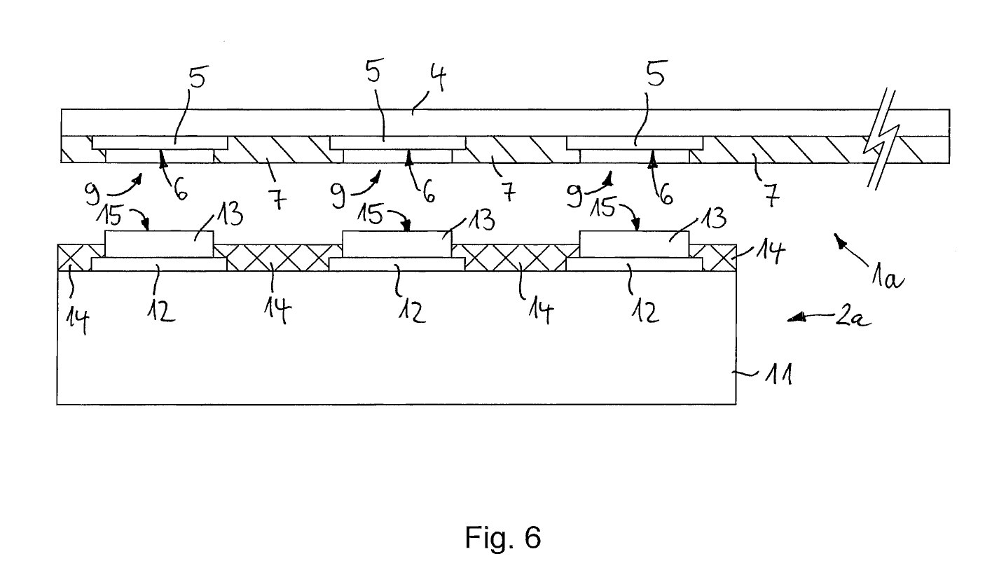

FIG. 6 a partial cross-section through a first illustrative embodiment of an assembly, which comprises the first ribbon cable and a first solid body, wherein the cable and the solid body are positioned in relation to each other in a pre-assembly position,

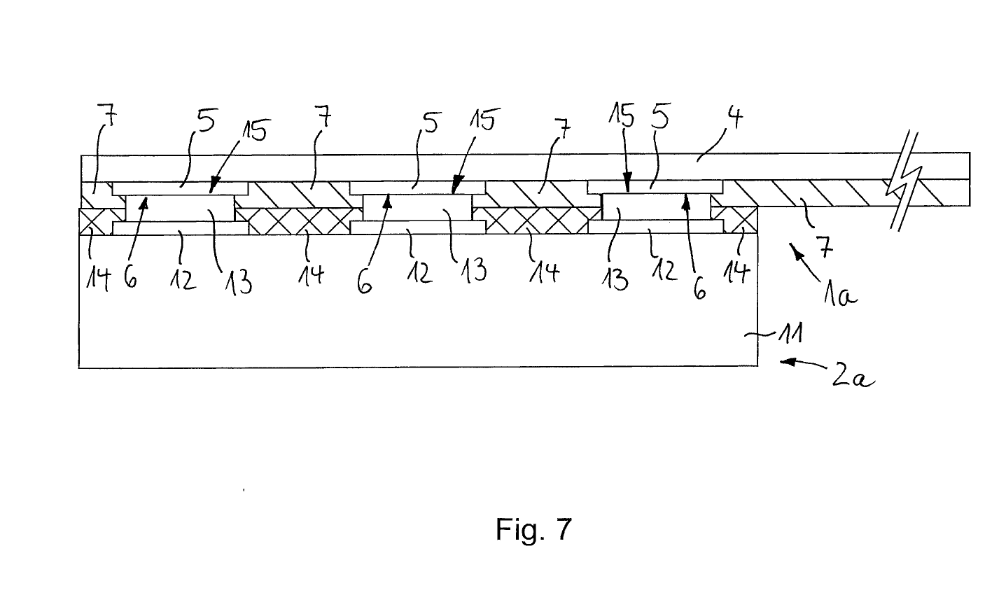

FIG. 7 a partial cross-section through the first illustrative embodiment of the assembly, wherein the cable and the solid body are aligned in the connection position,

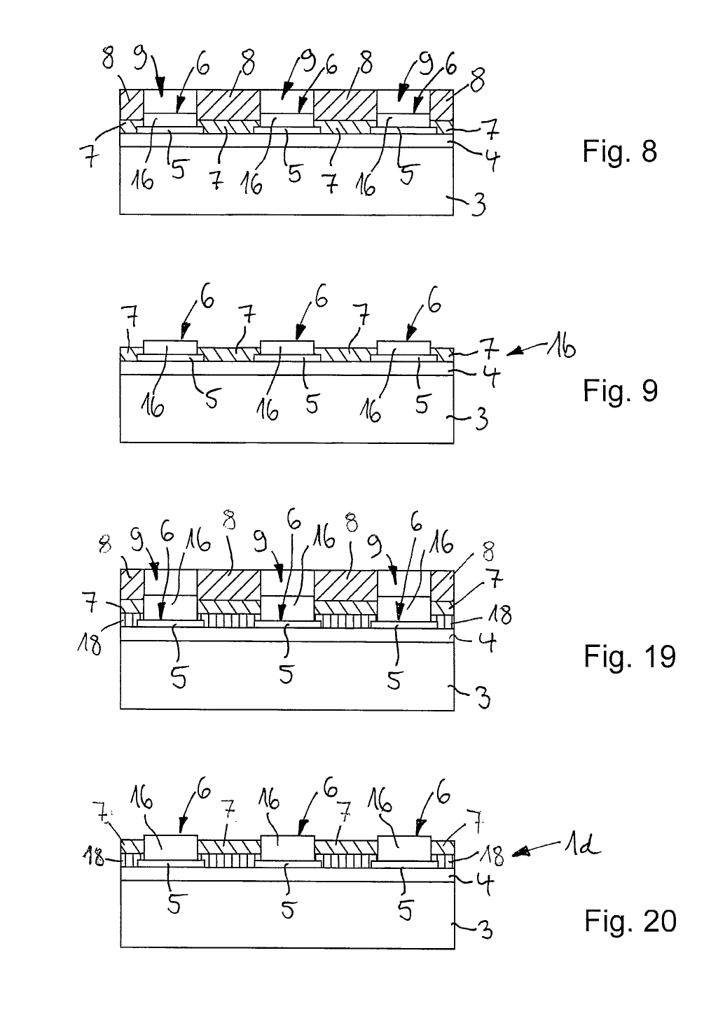

FIGS. 8

and 9 a cross-section through an auxiliary substrate, on which were applied layers for the manufacture of a second flexible ribbon cable,

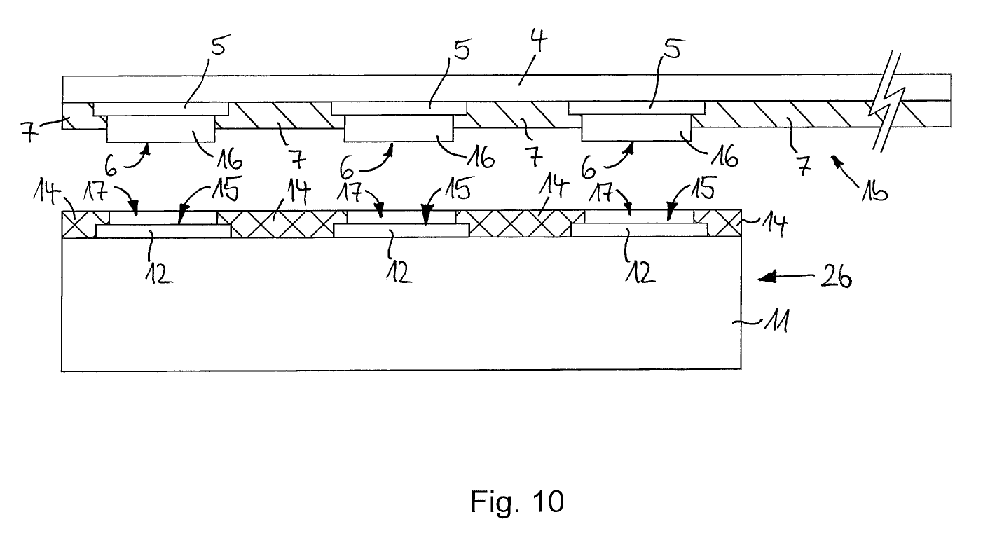

FIG. 10 a partial cross-section through a second illustrative embodiment of an assembly, which comprises the second ribbon cable and a second solid body, wherein the cable and the solid body are positioned in relation to each other in a pre-assembly position,

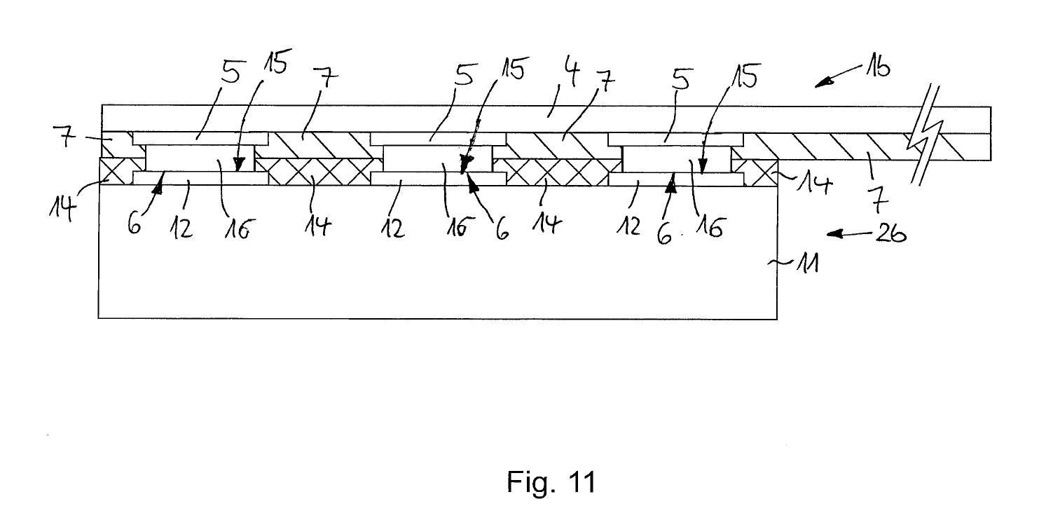

FIG. 11 a partial cross-section through the second illustrative embodiment of the assembly, wherein the cable and the solid body are aligned in the connection position,

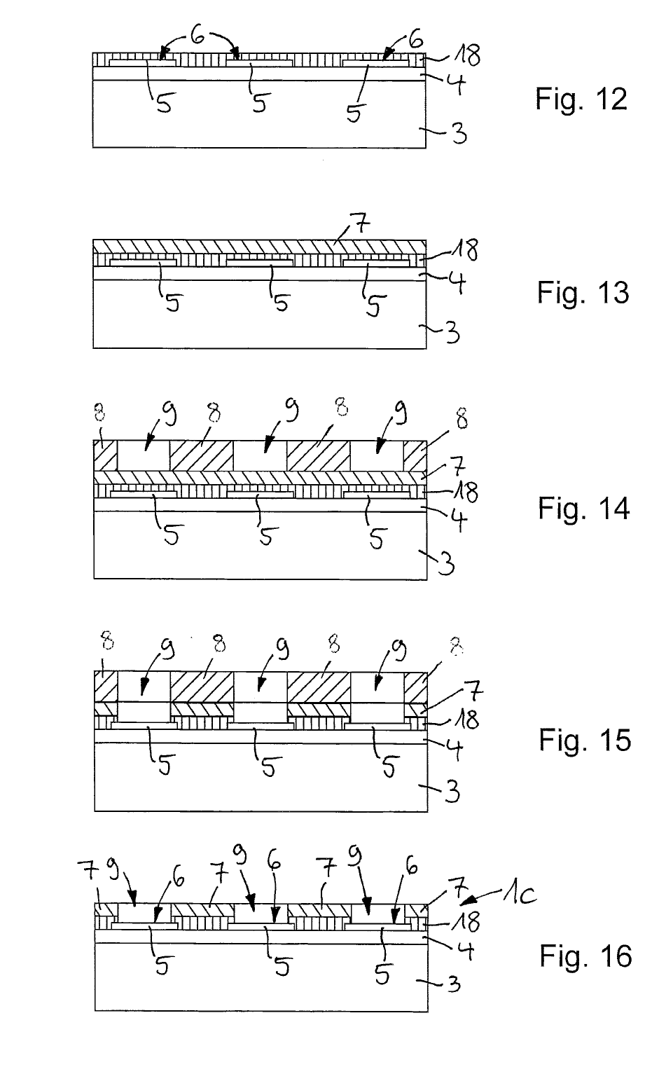

FIGS. 12

through 16 a cross-section through an auxiliary substrate, on which were applied layers for the manufacture of a third flexible ribbon cable,

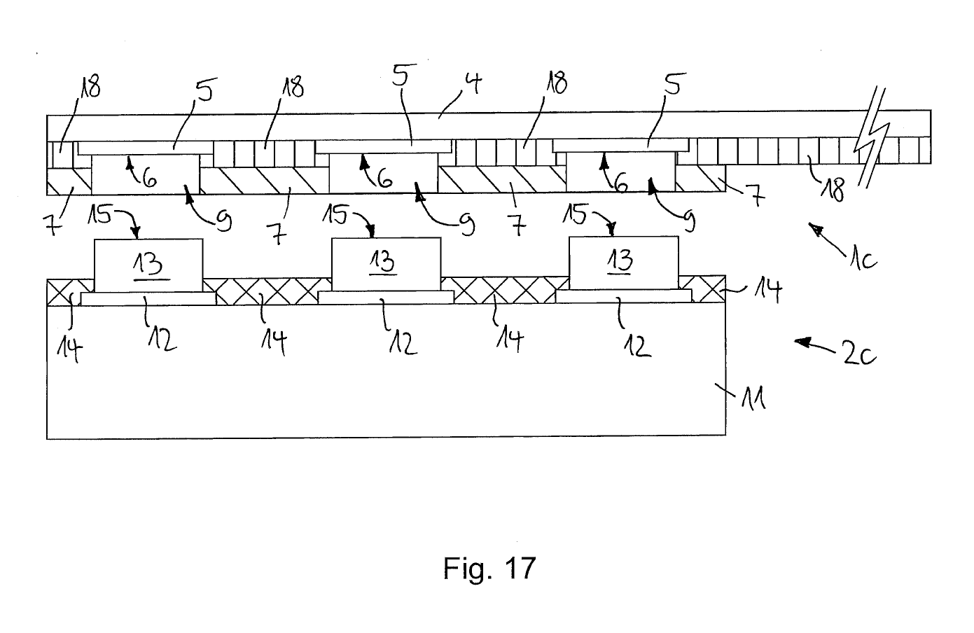

FIG. 17 a partial cross-section through a third illustrative embodiment of an assembly, which comprises the third ribbon cable and a third solid body, wherein the cable and the solid body are positioned in relation to each other in a pre-assembly position,

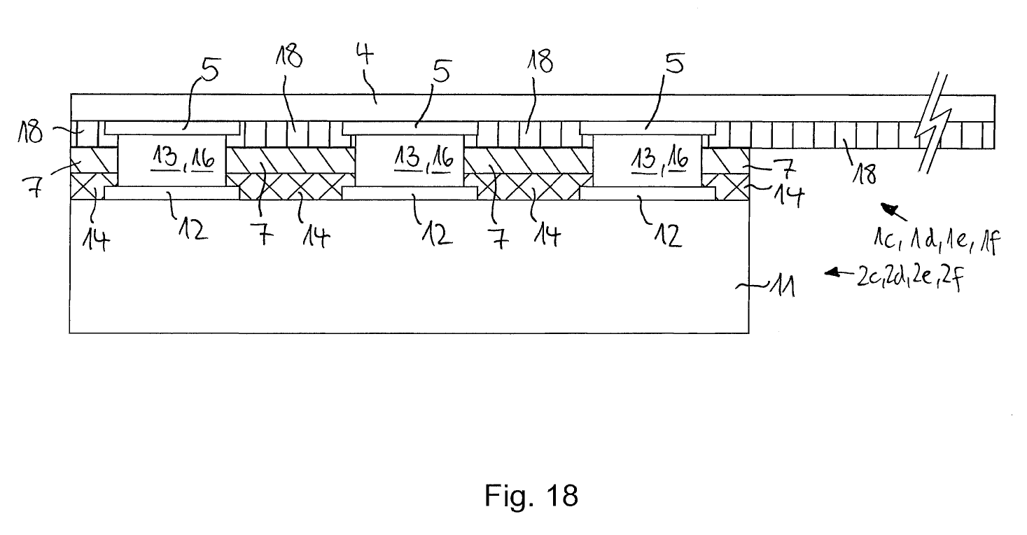

FIG. 18 a partial cross-section through the third, fourth, fifth, and sixth illustrative embodiment of the assembly, wherein the cable and the solid body are aligned in the connection position,

FIGS. 19

and 20 a cross-section through an auxiliary substrate, on which were applied layers for the manufacture of a fourth flexible ribbon cable,

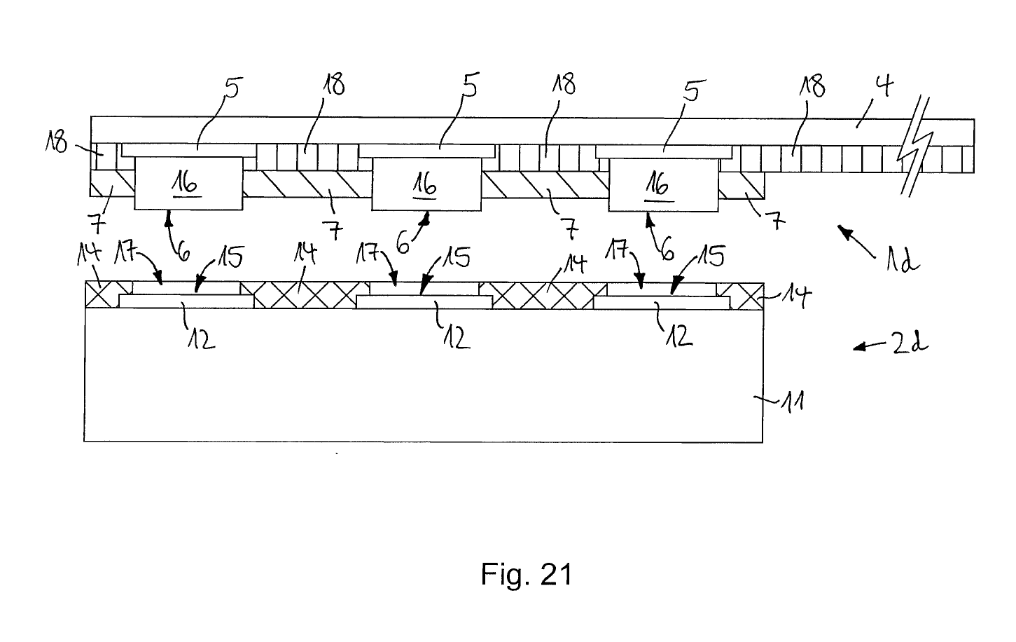

FIG. 21 a partial cross-section through a fourth illustrative embodiment of an assembly, which comprises the fourth ribbon cable and a fourth solid body, wherein the cable and the solid body are positioned in relation to each other in a pre-assembly position,

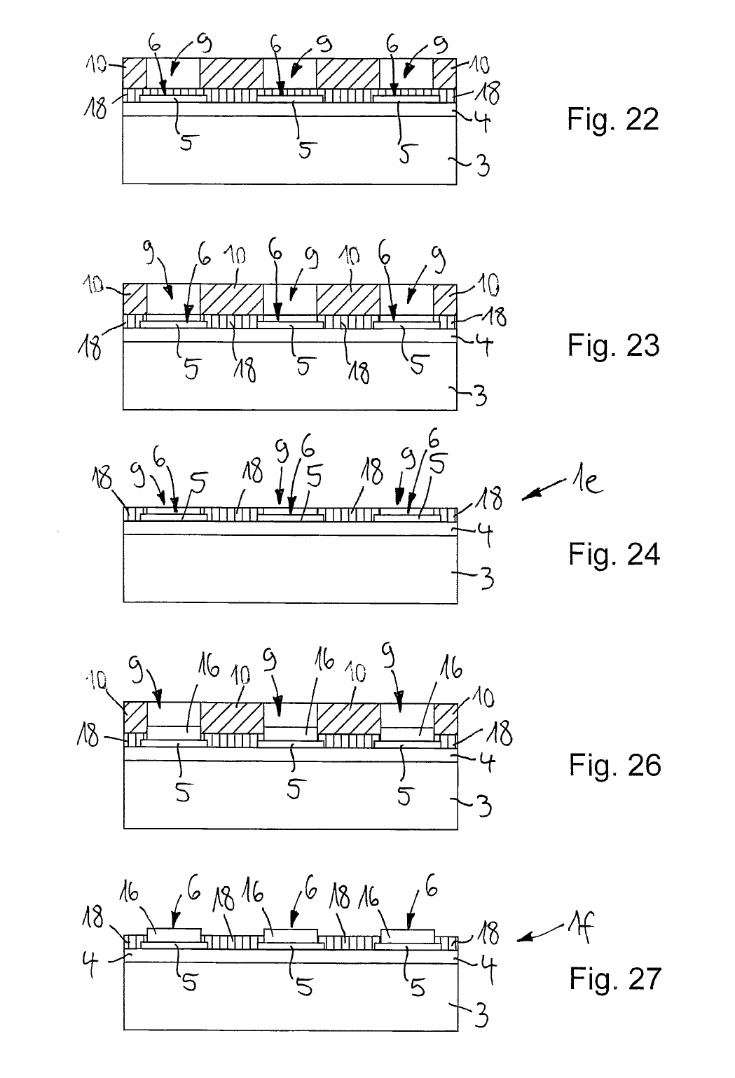

FIGS. 22

through 24 a cross-section through an auxiliary substrate, on which were applied layers for the manufacture of a fifth flexible ribbon cable,

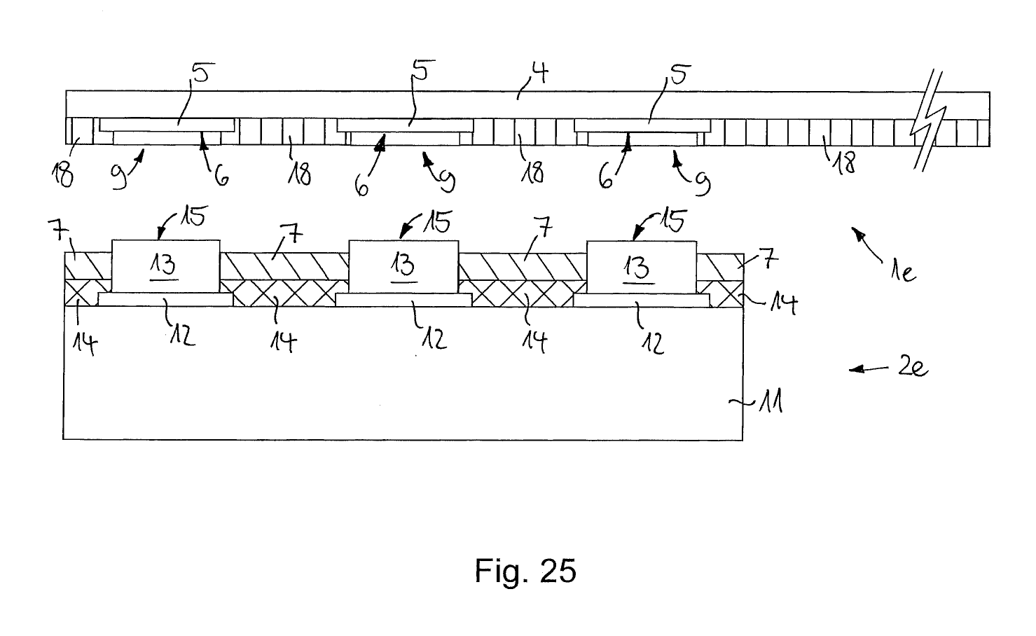

FIG. 25 a partial cross-section through a fifth illustrative embodiment of an assembly, which comprises the fifth ribbon cable and a fifth solid body, wherein the cable and the solid body are positioned in relation to each other in a pre-assembly position,

FIGS. 26

and 27 a cross-section through an auxiliary substrate, on which were applied layers for the manufacture of a sixth flexible ribbon cable, and

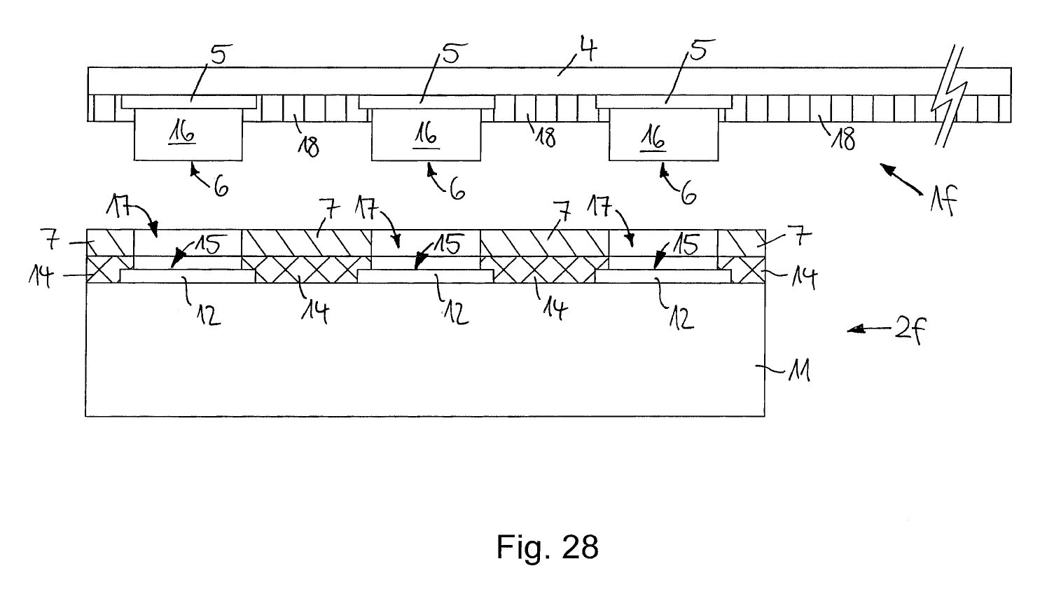

FIG. 28 a partial cross-section through a sixth illustrative embodiment of an assembly, which comprises the sixth ribbon cable and a sixth solid body, wherein the cable and the solid body are positioned in relation to each other in a pre-assembly position.

In a first illustrative embodiment of the method for producing an electrical connection, provision is made of a flexible, flat first cable 1a and a first solid body 2a. For manufacturing the first cable 1a, a flat support layer 4 made of an electrically insulating, flexible, elastically deformable material is applied on an auxiliary substrate 3 (FIG. 1). The cable material has a bending stiffness El of around 1.5 mNmm². The bending stiffness of the cable 1a standardized on the width B of the cable 1a El/B is between 0.1 Nmm and 7.5 Nmm. Preference is given to a standardized bending stiffness El/B with a value of around 0.75 Nmm. The support layer can comprise a polymer material. In this case preference is given to a thickness of the support layer of between 1 μm and 50 μm.

On the support layer 4 is formed a plurality of strip conductors 5 laterally spaced apart from each other. Each strip conductor 5 has an electric contacting point 6 facing away from the support layer 4. The contacting point 6 is made of gold or another suitable material. The strip conductors 5 can also be made of a conductive polymer. Preference is given to the strip conductors 5 having a thickness of between 50 nm and 1 μm, but they can also be thicker if the material comprising the strip conductors is sufficiently elastic.

In FIG. 2 it can be discerned that an adhesive layer 7 is applied on the entire support layer 4 plated with the conductor strips 5, wherein said adhesive layer 7 adheres to the support layer 4 and covers the conductor strips 5. The adhesive layer 7 can comprise a fluoride polymer, which can be applied to the support layer 4 by means of, say, a rotational casting process. The thickness of the adhesive layer 7 can reside within a range of 1 μm to 10 μm, wherein preference is given to ca. 4 μm. However, it can also be thicker.

On the adhesive layer 7 is applied a photomask 8, which adheres thereon and which has openings 9 over the contacting points 6 (FIG. 3). To remove the areas of the adhesive layer 7 from within the openings 9, the photomask 8 is brought into contact with a solvent for the adhesive layer 7 (FIG. 4). Afterwards the photomask 8 is removed from the adhesive layer 7 (FIG. 5). Each individual contacting point 6 is now uninterruptedly surrounded by the adhesive layer 7 in a plane parallel to the extension plane of the support 4.

In FIG. 6 it can be discerned that the first solid body 2a has a support 11, say, a semiconductor chip, which has an electrically insulating surface facing the cable 1a in an assembly position and an electroplating 12a. If the support 11 is composed of silicon, its thickness should not be less than 50 μm. Materials other than silicon are also conceivable.

On the electroplating 12 is disposed a plurality of contact structures 13, which are laterally spaced apart from each other by an electrically insulating support zone 14, i.e., a passivation layer. The insulating support zone 14 can be made of silicon oxide, silicon nitride, or ceramics and/or polymers. For silicon nitride, thickness between 100 nm and 5 μm are practical. For polymers, greater thicknesses are also conceivable.

The contact structures 13 are preferably made of gold or another suitable, preferably a galvanically precipitable material. Each contact structure 13 has a contact zone 15 facing away from the support 11 and protruding relative to the surface of the support zone 14 facing away from the support 11 perpendicular to the extension plane of the support 11 by ca. 2-10 μm.

The assembly comprising the auxiliary substrate 3 and the first cable 1a and the first solid body 2a are now brought into a pre-assembly position, in which each individual contacting point 6 of the first cable 1a faces an assigned contact zone 15 of the first solid body 2a and is oppositely disposed relative thereto. For the sake of clarity, the auxiliary substrate 3 is not shown in any greater detail in the pre-assembly position illustrated in FIG. 6. In lieu of the auxiliary substrate 3, it is also possible to use another, essentially rigid support element on which the cable 1a is fastened, preferably by negative pressure. It is clearly discernible that in the pre-assembly position, each individual contact zone 15 is aligned directly opposite an opening 9 of the adhesive layer.

The assembly and the first solid body 2a are then brought in proximity to each other in such a way that each contacting point 6 contacts its assigned contact zone 15 and the adhesive layer 7 flatly comes to rest on and adheres to the surface of the first solid body 2a facing said adhesive layer 7 (FIG. 7). Each contact area 15 engages in an opening 9 of the adhesive layer 7. The cross-section of the opening 9 is somewhat larger than that of the contact structures 13, so that a narrow, lateral gap that cannot be seen in the drawing is maintained between the contact structures 13 and the adhesive layer 7.

With the aid of ultrasound, the contact zones 15 are welded to the contacting points 6. Simultaneously, the rim zones of the adhesive layer 7 laterally adjacent to the openings 9 are heated above the vitrification temperature and by applying pressure are displaced towards the contact structure 13 in such a way that the adhesive layer 7 laterally contacts the contact structure 13. The rim zones are now cooled below the vitrification temperature. Afterwards the auxiliary substrate 3 or the support element is detached from the cable 1a. The first cable 1a is now electrically and mechanically connected to the first solid body 2a. In FIG. 7, it can be discerned that the contacting points 6 and the contact zones 15 are encapsulated by the adhesive layer 7.

In a second illustrative embodiment of the invention, initially the same steps shown in FIGS. 1-4 are carried out for manufacturing a second cable 1b. Afterwards the zones of the strip conductors 5 residing in the openings 9 are in each case plated with a contacting structure 16, which projects above the surface of the adhesive layer 7 facing away from the auxiliary substrate 3 (FIG. 8). The photomask 8 is then removed from the adhesive layer 7 (FIG. 9). In this illustrative embodiment as well, each individual contacting point 6 is uninterruptedly surrounded by the adhesive layer 7 in a plane extending parallel to the extension plane of the support layer 4.

In FIG. 10 it can be discerned that provision is made of a second solid body 2b, which has a support 11 with an electroplating 12 applied on its surface. The electroplating 12 comprises a plurality of contact zones 15 laterally spaced apart from each other, which face away from the support 11 and which are disposed in recesses 17 formed in an electrically insulating support zone 14.

The assembly comprising the auxiliary substrate 3 and the second cable 1b and the second solid body 2b are brought into a pre-assembly position, in which each individual contacting point 6 of the second cable 1b faces an assigned contact zone 15 of the second solid body 2b and is oppositely disposed relative thereto. It can be clearly discerned in FIG. 10 that each individual contacting point 6 is aligned directly opposite a recess 17 of the support zone 14. For the sake of clarity, the auxiliary substrate 3 is not shown in any greater detail in FIG. 10. In lieu of the auxiliary substrate 3, it is also possible to use another, essentially rigid support element.

The assembly comprising the second cable 1b and the second solid body 2b are brought in proximity to each other in such a way that each contacting point 6 contacts its assigned contact zone 15 and the adhesive layer 7 flatly comes to rest on and adheres to the surface of the second solid body 2b facing said adhesive layer 7 (FIG. 11). Each contacting point 6 engages in a recess 17 of the electrically insulating support zone 14, wherein a lateral, narrow gap, which is not shown in any greater detail in the drawing, is formed between the contacting structures 16 and the support zone 14.

With the aid of ultrasound, the contact zones 15 are now welded to the contacting points 6. Simultaneously, the rim zones of the adhesive layer 7 laterally adjacent to the contacting structures 16 are heated above the vitrification temperature and by applying pressure are displaced area-wise into the recesses 17. The rim zones are then cooled below the vitrification temperature. Afterwards the auxiliary substrate 3 or the support element is detached from the second cable 1b. The adhesive layer 7 surrounds and forms a seal around the contact zones 15 and the contacting structures 16.

In a third illustrative embodiment of the invention, for manufacturing a third cable 1c a flat support surface 4 made of an electrically insulating material is applied to an auxiliary substrate 3 (FIG. 1). On the support surface 4 is formed a plurality of conductor strips 5, which are laterally spaced apart from each other. Each conductor strip 5 has an electrical contacting point 6, which faces away from the support layer 4.

It can be discerned in FIG. 12 that a polymer layer 18 is applied on the entire support layer 4 plated with the strip conductors 5, wherein the polymer layer adheres to said support layer 4 and covers said strip conductors 5. The polymer layer 18 can be made of the same material, e.g., polyimide and/or Parylene, as the support layer 4. The polymer layer 18 can also be made of a different material than the support layer 4, provided that this material is sufficiently flexible. An adhesive layer 7 containing a fluoride polymer is applied to the whole surface of the polymer layer 18 (FIG. 13). A photomask 8 having openings 9 over the contacting points 6 is applied to the adhesive layer 7 (FIG. 14).

To remove the portions of the adhesive layer 7 and the polymer layer 18 from within the openings 9, the photomask 8 is brought into contact with a solvent for the adhesive layer 7 and the polymer layer 18 (FIG. 15). The photomask 8 is then removed from the adhesive layer 7 (FIG. 16).

Provision is made of a third solid body 2c illustrated in FIG. 17, which comprises a support 11 that has an electroplating 12 on its surface. On the electroplating 12 is disposed a plurality of contact structures 13, which are laterally spaced apart from each other by an electrically insulating support zone 14. Each of the contact structures 13 has a contact zone 15 facing away from the support 11, which protrudes relative to the surface of the support zone 14 facing away from the support 11 perpendicular to the extension plane of the support 11 by about 2-10 μm.

The assembly comprising the auxiliary substrate 3 and the third cable 1c and the third solid body 2c are brought into a pre-assembly position, in which each individual contacting point 6 of the third cable 1c faces an assigned contact zone 15 of the third solid body 2c and is oppositely disposed relative thereto. It can be discerned in FIG. 17 that in the pre-assembly position, each individual contact zone 15 is aligned directly opposite an opening 9 of the adhesive layer 7 and the polymer layer 18. For the sake of clarity, the auxiliary substrate 3 is not shown in any greater detail in FIG. 17. In lieu of the auxiliary substrate 3, another essentially rigid support element can also be used.

The assembly comprising the third cable 1c and the third solid body 2c are now brought in proximity to each other until each contacting point 6 contacts its assigned contact zone 15 and the adhesive layer 7 flatly comes to rest on and adheres to the surface of the third solid body 2c facing said adhesive layer 7 (FIG. 18). Each contact structure 13 engages in an opening 9 of the adhesive layer 7 and the polymer layer 18, wherein a lateral narrow gap not shown in any greater detail in the drawing is formed between each contact structure 13 and the adhesive layer 7.

With the aid of ultrasound, the contact zones 15 are welded to the contacting points 6. Simultaneously, the rim zones of the support zone 14 laterally adjacent to the openings 9 are heated above the vitrification temperature and by applying pressure are displaced towards the contact structure 13 in such a way that the adhesive layer 7 laterally contacts the contact structure 13. The rim zones are now cooled below the vitrification temperature. Afterwards the auxiliary substrate 3 or the support element is detached from the third cable 1c.

In a fourth illustrative embodiment of the invention, the procedural steps illustrated in FIGS. 1 and 12-15 are initially carried out for manufacturing a fourth cable 1d. What was said above likewise applies to these procedural steps.

A contacting structure 16 that contacts the strip conductor 5 in the opening 9 is then inserted in each of the openings 9. In FIG. 19 it can be discerned that the contacting structure 16 projects above the surface of the adhesive layer 7 facing away from the auxiliary substrate 3. The photomask 8 is removed from the adhesive layer 7 after the contacting structures 16 are formed (FIG. 20).

In FIG. 21 it can be discerned that provision is made of a fourth solid body 2d, which has a support 11 with an electroplating 12 applied on its surface. The electroplating 12 comprises a plurality of contact zones 15 laterally spaced apart from each other, which face away from the support 11 and are disposed in recesses 17 formed in an electrically insulating support zone 14.

The fourth cable 1d and the fourth solid body 2d are brought into a pre-assembly position, in which each individual contacting point 6 of the fourth cable 1d faces an assigned contact zone 15 of the fourth solid body 2d and is oppositely disposed relative thereto. It can be discerned in FIG. 21 that in the pre-assembly position, each individual contacting point 6 is aligned directly opposite a recess 17 of the support area 14. For the sake of clarity, the auxiliary substrate 3 is not shown in any greater detail in FIG. 21. In lieu of the auxiliary substrate 3, it is also possible to use another, essentially rigid support element.

The assembly comprising the auxiliary substrate 3 and the fourth cable 1d and the fourth solid body 2d are now brought in proximity to each other until each contacting point 6 contacts its assigned contact zone 15 and the adhesive layer 7 flatly comes to rest on and adheres to the surface of the fourth solid body 2d facing said adhesive layer 7 (FIG. 18). Each contacting structure 16 engages in a recess 17 of the support zone 14, wherein a lateral narrow gap not shown in any greater detail in the drawing is formed between each contacting structure 16 and the support zone 14.

With the aid of ultrasound, the contact zones 15 are now welded to the contacting points 6. Simultaneously, the rim zones of the adhesive layer 7 laterally adjacent to the contacting structures 16 are heated above the vitrification temperature and by applying pressure are displaced area-wise into the recesses 17. The rim zones are then cooled below the vitrification temperature. Afterwards the auxiliary substrate 3 or the support element is detached from the fourth cable 1d.

In a fifth illustrative embodiment of the invention, for manufacturing a fifth cable 1e the procedural steps illustrated in FIGS. 1 and 12 are carried out initially. A photomask 10 that has openings 9 over the contacting points 6 is then applied to the polymer layer 18 (FIG. 22).

To remove the areas of the polymer layer 18 from within the openings 9, the photomask 10 is brought into contact with a solvent for the polymer layer 18 (FIG. 23). Afterwards the photomask 10 is removed from the polymer layer 18 (FIG. 24).

As can be discerned in FIG. 25, provision is made of a fifth solid body 2e, which has a support 11 with an electroplating 12 applied on its surface. The electroplating 12 comprises a plurality of zones laterally spaced apart from each other, which are disposed in recesses formed in an electrically insulating support zone 14 and an adhesive layer 7 disposed thereon and adhering thereto. The adhesive layer 7 is made of a fluoride polymer and has a thickness of around 4 μm. On the electroplating 12 are disposed contact structures 13, each of which has a contact zone 15 facing away from the support 11 and protruding ca. 2-10 μm relative to the surface of the adhesive layer 7 facing away from the support 11 perpendicular to the extension plane of said support 11. The contact structures 13 are electrochemically deposited on the electroplating 12 during the manufacture of the fifth solid body 2e.

The assembly comprising the auxiliary substrate 3 and the fifth cable 1e and the fifth solid body 2e are brought into a pre-assembly position, in which each individual contacting point 6 of the fifth cable 1e faces an assigned contact zone 15 of the fifth solid body 2e and is oppositely disposed relative thereto. In FIG. 25 it can be discerned that in the pre-assembly position, each individual contact zone 15 is aligned directly opposite an opening 9 of the polymer layer 18. For the sake of clarity, the auxiliary substrate 3 is not shown in any greater detail in FIG. 25. In lieu of the auxiliary substrate 3, it is also possible to use another, essentially rigid support element.

The fifth cable 1e and the fifth solid body 2e are now brought in proximity to each other until each contacting point 6 contacts its assigned contact zone 15 and the adhesive layer 7 flatly comes to rest on and adheres to the surface of the fifth cable 1e facing said adhesive layer 7 (FIG. 18). Each contacting structure 13 engages in an opening 9 of the polymer layer 18, wherein a lateral, narrow gap, which is not shown in any greater detail in the drawing, is formed between the contact structures 13 and the polymer layer 18.

With the aid of ultrasound, the contact zones 15 are welded to the contacting points 6. Simultaneously, the rim zones of the polymer layer 18 laterally adjacent to the contact structures 13 are heated above the vitrification temperature and by applying pressure are displaced area-wise into the gap. The rim zones are then cooled below the vitrification temperature. Afterwards the auxiliary substrate 3 or the support element is detached from the fifth cable 1e.

In a sixth illustrative embodiment of the invention for manufacturing a sixth cable if the procedural steps illustrated in FIGS. 1, 12, 22, and 23 are carried out initially. Contacting structures 16 are then mounted on the strip conductors 5 inside the openings 9 (FIG. 26). Each contacting structure 16 has a contact area 6 facing away from the support layer 4, which protrudes relative to the surface of the polymer layer 18 facing away from the support layer 4 perpendicular to the extension plane of the support layer 4 by about 2-10 μm. Afterwards the photomask 10 is removed from the polymer layer 18 (FIG. 27).

As can be discerned in FIG. 28, provision is made of a sixth solid body 2f, which comprises a support 11 with an electroplating 12 applied on its surface. The electroplating 12 has a plurality of zones laterally spaced apart from each other, which are disposed in recesses 17 formed in an electrically insulating support zone 14 and an adhesive layer 7 disposed thereon and adhering thereto. On its surface facing away from the support 11, the electroplating 12 has electrical contact zones 15, which are disposed underneath the adhesive layer 7.

The assembly comprising the auxiliary substrate 3 and the sixth cable 1f and the sixth solid body 2f are brought into a pre-assembly position, in which each individual contacting point 6 of the sixth cable 1f faces an assigned contact zone 15 of the sixth solid body 2f and is oppositely disposed relative thereto. In FIG. 28 it can be discerned that in the pre-assembly position, each individual contacting point 6 is aligned directly opposite a recess 17 penetrating the adhesive layer 7 and the support zone 14.

The sixth cable 1f and the sixth solid body 2f are now brought in proximity to each other until each contacting point 6 contacts its assigned contact zone 15 and the adhesive layer 7 flatly comes to rest on and adheres to the surface of the sixth cable 1f facing said adhesive layer 7 (FIG. 18). Each contacting structure 16 engages in a recess 17 of the adhesive layer 7 or the electrically insulating support zone 14, wherein a lateral, narrow gap, which is not shown in any greater detail in the drawing, is formed between the contacting structures 16 and the adhesive layer 7.

With the aid of ultrasound, the contact zones 15 are now welded to the contacting points 6. Simultaneously, the rim zones of the adhesive layer 7 laterally adjacent to the recesses 17 are heated above the vitrification temperature and by applying pressure are displaced towards the contacting structures 16 in such a way that the adhesive layer 7 laterally contacts the contacting structures 16. The rim zones are then cooled below the vitrification temperature. Afterwards the auxiliary substrate 3 or the support element is detached from the sixth cable 1f.

Mention should still be made that in principle, the use of any adhesive as an adhesive layer 7 is conceivable. If the adhesive layer 7 is disposed on the cable 1a, 1b, 1c, 1d, 1e, 1f, it must be sufficiently flexible.

1. A method for producing an electrical and mechanical connection, wherein provision is made of a solid body comprising a support, on the surface of which is disposed at least one electrical contact zone and an electrically insulating support zone surrounding the latter, wherein provision is made of a flexible, flat cable comprising at least one planar support layer made of an electrically insulating material and at least one strip conductor disposed thereon, which has at least one electrical contacting point with a laterally adjacent electrically insulating cable zone on the surface of the cable, and wherein the cable and the solid body are positioned in relation to each other in a pre-assembly position and the contact zone is electrically connected to the contacting point, wherein an adhesive layer is applied to the surface of the cable and the contacting point is disposed on the support layer in such a way that the adhesive layer surrounds the contacting point and adheres to the surface of the cable, further wherein the solid body and the cable are then positioned in relation to each other in the pre-assembly position in such a way that the contacting point of the cable is facing the contact zone of the solid body and the adhesive layer is facing the electrically insulating support zone, and still further wherein the solid body and the cable are then positioned against each other in such a way that the contacting point electrically contacts the contact zone and the adhesive layer adheres to the surface of the solid body.

2. The method as in claim 1, wherein provision is made of the solid body in such a way that the contact zone protrudes relative to a laterally adjacent surface zone of the solid body perpendicular to the extension plane of the support, further wherein the adhesive layer and the contacting point are positioned in such a way on the surface of the cable and on the surface of the support layer, respectively, that the adhesive layer has an opening at the contacting point and with its rim zone surrounding the opening perpendicular to the plane in which the cable extends, protrudes relative to the contacting point, and still further wherein the solid body and the cable are positioned against each other in such a way that the contact zone contacts the contacting point through the opening.

3. The method as in claim 2, wherein the cross-section of a section of the opening for accommodating the contact structure in the assembly position is somewhat larger than the cross-section of the protruding part of the contact structure, further wherein during and/or after the positioning of the solid body and the cable against each other, at least the rim zone of the adhesive layer adjacent to the opening is heated above the vitrification temperature of the adhesive layer, still further wherein pressure is applied to the rim zone in such a way that the latter is displaced towards the contact structure and comes into contact with the contact structure, and even still further wherein the temperature of the rim zone is cooled below the vitrification temperature afterwards.

4. The method as in claim 1, wherein the cable is manufactured by the adhesive layer and a contacting structure being applied to the support layer in such a way that the contacting structure protrudes relative to a laterally adjacent surface zone of the adhesive layer perpendicular to the extension plane of the support layer and forms the contacting point on its fee end zone facing away from the support layer, further wherein the contact zone is disposed in a recess of the support zone, and still further wherein the solid body and the cable are then positioned against each other in such a way that the contacting point contacts the contact zone through the recess.

5. The method as in claim 4, wherein the cross-section of a section of the recess for accommodating the contacting structure in the assembly position is somewhat larger than the cross-section of the part of the contacting structure protruding from the surface zone of the adhesive layer, further wherein during and/or after the positioning of the solid body and the cable against each other, at least the rim zone of the adhesive layer adjacent to the recess is heated above the vitrification temperature of the rim zone, still further wherein pressure is applied to the rim zone in such a way that the latter comes into contact in the recess with the contacting structure and/or the support zone, and even still further wherein the temperature of the rim zone is cooled below the vitrification temperature afterwards.

6. The method for manufacturing an electrical and mechanical connection, wherein provision is made of a solid body comprising a support with at least one electrical contact zone and an electrically insulating support zone surrounding the latter disposed on its surface, wherein provision is made of a flexible, flat cable comprising at least one planar support layer made of an electrically insulating material and at least one strip conductor disposed thereon, said strip conductor having at least one electrical contacting point with a laterally adjacent electrically insulating cable zone on the surface of the cable, and wherein the cable and the solid body are positioned in relation to each other in a pre-assembly position and the contact zone is electrically connected to the contacting point, wherein an adhesive layer is applied to the surface of the solid body and the contact zone is disposed on the support in such a way that the adhesive layer surrounds the contact zone and adheres to the surface of the solid body, further wherein the solid body and the cable are then positioned in relation to each other in the pre-assembly position in such a way that the contacting point of the cable faces the contact zone of the support and the adhesive layer faces the electrically insulating cable zone, and still further wherein the solid body and the cable are then positioned against each other in such a way that the contacting point electrically contacts the contact zone and the adhesive layer adheres to the surface of the cable.

7. The method as in claim 6, the adhesive layer is applied to the surface of the solid body and the contact zone is disposed on the support in such a way that the contact structure protrudes relative to a laterally adjacent surface zone of the adhesive layer perpendicular to the extension plane of the surface zone and forms the contact zone on its free end zone facing away from the support, further wherein the contacting point is disposed in an opening of the electrically insulating cable zone, and still further wherein the solid body and the cable are then positioned against each other afterwards in such a way that the contact zone contacts the contacting point through the recess.

8. The method as in claim 7, wherein the cross-section of a section of the opening for accommodating the contact structure in the assembly position is somewhat larger than the cross-section of the part of the contact structure protruding relative to the surface zone of the adhesive layer, further wherein during and/or after the positioning of the solid body and the cable against each other, at least the rim zone of the adhesive layer laterally adjacent to the opening is heated above the vitrification temperature of the rim zone, still further wherein pressure is applied to the rim zone in such a way that the latter comes into contact in the recess with the contact structure and/or the electrically insulating cable zone, and even still further wherein the temperature of the rim zone is cooled below the vitrification temperature afterwards.

9. The method as in claim 6, wherein the adhesive layer and the contact zone are mounted on the support in such a way that the adhesive layer has a recess on the contact zone and with its rim zone surrounding the recess perpendicular to the extension plane of the support, protrudes relative to the contact zone, further wherein a contacting structure is mounted on the support layer in such a way that it protrudes relative to a laterally adjacent surface zone of the electrically insulating cable zone perpendicular to the extension plane of the surface zone and forms the contacting point on its free end zone facing away from the support layer, and still further wherein the solid body and the cable are then positioned against each other in such a way that the contacting point contacts the contact zone through the recess.

10. The method as in claim 9, wherein the cross-section of a section of the recess for accommodating the contacting structure in the assembly position is somewhat larger than the cross-section of the part of the contacting structure protruding relative to the surface area of the electrically insulating cable zone, further wherein during and/or after the positioning of the solid body and the cable against each other, at least the rim zone of the adhesive layer laterally adjacent to the recess is heated above the vitrification temperature of the rim zone, still further wherein pressure is applied to the rim zone in such a way that the latter comes into contact with the contacting structure, and even still further wherein the temperature of the rim zone is cooled below the vitrification temperature afterwards.

11. The method as in claim 1, wherein during and/or after the positioning of the solid body and the cable against each other, the contacting point is welded by ultrasound to the contact zone.

12. The method as in claim 1, wherein a polymer layer is applied as an electrically insulating cable zone to the support layer and an electroplating.

13. The method as in claim 1, wherein the cable is fastened onto an essentially rigid support element and brought into the pre-assembly position together with the support element, and the assembly comprising the support element and the cable on one hand and the solid body on the other hand are then positioned in relation to each other in such a way that the contacting point electrically contacts the contact zone, and in that the support element is separated from the cable afterwards.

14. An assembly comprising a flexible, flat cable and a solid body connected thereto, wherein the solid body has a support with at least one electrical contact zone and an electrically insulating support zone surrounding said contact zone disposed on its surface, wherein the cable has at least one planar support layer made of an electrically insulating material and at least one strip conductor disposed thereon, which has at least one electrical contacting point with a laterally adjacent electrically insulating cable zone on the surface of the cable, and wherein the contacting point is electrically connected to the contact zone, wherein the contacting point is facing the contact zone, and in that between the cable and the solid body is disposed an adhesive layer surrounding the contacting point and the contact zone, which planarly adheres to the surface of the solid body and to the surface of the cable.

15. The assembly as in claim 14, wherein the contacting point is welded to the contact zone using ultrasound.

16. The assembly as in claim 14, wherein a polymer layer is disposed on the support layer, further wherein provision is made of at least one strip conductor between the support layer and the polymer layer, still further wherein the polymer layer has at least one opening in which is disposed a contacting structure comprising the contacting point and electrically connected to the strip conductor, and even still further wherein the adhesive layer adheres to a surface zone of the polymer layer facing away from the support layer.

17. The assembly as in claim 14, wherein the thickness of the cable is less than 50 μm, if necessary less than 30 μm, particularly less than 20 μm, and preferably less than 12 μm.
